(19) United States
(12) Patent Application Publication
(10) Pub. No.: US 2024/0429478 A1
(43) Pub. Date: Dec. 26, 2024

(54) BATTERY AND BATTERY CONTROL METHOD

(71) Applicant: Webasto SE, Stockdorf (DE)

(72) Inventor: Samantha Zimnik, Stockdorf (DE)

(21) Appl. No.: 18/684,004

(22) PCT Filed: Aug. 23, 2022
(86) PCT No.: PCT/EP2022/073385

§ 371 Date: Feb. 15, 2024

(30) Foreign Application Priority Data
Aug. 23, 2021 (DE) 102021121742.3

(51) Int. Cl. H01M 10/48; H01M 10/42

(52) U.S. Cl. CPC H01M 10/488; H01M 10/425; H01M 10/486; H01M 2010/4271; H01M 2220/20

(57) ABSTRACT

The present invention relates to a method for operating a battery, which includes

determining the cell voltage of at least one battery cell,

determining the associated cell pack voltage of the at least one battery cell, and

evaluating the cell voltage and the cell pack voltage by means of an analysis program on a microprocessor in a main control unit, where an overheating warning message is triggered if, within a defined measurement period, the cell voltage decreases by a defined cell error value and the cell pack voltage decreases by a defined pack error value.

### CROSS-REFERENCE TO RELATED APPLICATIONS

This application is a 35 U.S.C. § 371 National Stage Entry of International Application No. PCT/EP2022/073385 filed Aug. 23, 2022, which claims the priority benefit of German Patent Application Serial Number DE 10 2021 121 742.3 filed Aug. 23, 2021, all of which are incorporated herein by reference in their entirety for all purposes.

### TECHNICAL FIELD

The present invention relates to a method for operating a battery as per the preamble of claim 1 and to a battery as per the preamble of claim 10.

### BACKGROUND

Batteries, in particular HV batteries, which have a multiplicity of cell packs, are monitored with regard to electrical and physical states. This also includes monitoring thermal states, in particular detecting so-called thermal breakdown (thermal runaway). In order to detect a thermal event, in one or more cells of a battery or of a battery system the pressure or the pressure curve present in the interior of a battery is evaluated. This pressure measurement is performed, for example, by a pressure sensor which can be arranged on the main board, for example, as part of the battery management system (BMS). Such a “thermal event” (thermal runaway) is a state in which the heating increases independently due to chemical processes without any further external influence, such as, for example, the current load, and wherein the chemical process is simultaneously accelerated.

Such a monitoring arrangement is shown by DE 10 2018 210 975 B4, for example, in which a thermal event is detected by a pressure sensor arranged on a main board of the battery control unit. Accommodating the pressure sensor on the main board is disadvantageous because this main board has to be physically enlarged further for this purpose, thereby making it difficult to accommodate it in the battery and further complicating the verification of the data from the pressure sensor on the main board according to the ASIL standard.

Alternatively, in order to monitor thermal runaway, it is known to detect CO₂ being emitted, which, as a result of a cell being excessively heated, escapes from the electrolyte of the cell. The disadvantage of this solution is the temporal offset between the heating of the cell and the identification of the CO₂ at a particular point in the interior or outside of the battery by means of a suitable sensor.

### SUMMARY

It is the object of the present invention to propose improved and in particular faster detection of thermal runaway.

This object is achieved according to the invention by a method as per the features of claim 1 and a battery as per the features of claim 10. Advantageous configurations are specified in the respective, associated dependent claims.

The object is accordingly achieved by a method for operating a battery, in particular a high-voltage battery, which has a battery management system (BMS) having a main control unit, in particular having a main microprocessor, wherein monitoring or checking with regard to thermal events (thermal runaways) is performed by the method in recurring, in particular regular measurement periods. Furthermore, the battery comprises at least one, in particular a plurality of cell packs.

In the method according to the invention, the following steps are performed here:
determining the cell voltage of at least one (battery) cell,
determine the associated cell pack voltage of the at least one battery cell and evaluating the cell voltage and the cell pack voltage by means of an analysis program on a microprocessor, in particular in the main control unit. On the basis of the evaluation, an overheating warning message is triggered if, within a defined event time, the cell voltage decreases by a defined cell error value and the cell pack voltage likewise decreases by a defined pack error value.

An overheating warning message here should be understood to mean any warning signal and/or control signal which warns a user of the battery, such as for example the driver of a vehicle during use, in particular audibly or visually, and triggers at least partial switching off of the battery or other steps in order to bring about safe operation and/or switching off.

In an improved method variant, the cell error value is at least 60%, compared with the cell voltage before the measurement period; in particular the cell error value is at least 70%. Therefore, for example, if an output cell voltage is 4V, the critical cell error value=0.6×4V.

A further improved method variant makes provision for the pack error value to correlate with the cell error value and to correspond in size at least to the cell error value, with a fluctuation range of +/−10%, ideally +/−5%.

Surprisingly, it has turned out that a sudden drop in the cell voltage due to a short circuit does not necessarily have to constitute thermal runaway but, except for negligible individual cases, the aforementioned sudden drop in cell voltage and cell pack voltage precedes each thermal runaway.

In an improved method variant, the event time during which after a cell error value a pack error value is carried out or determined is in the range of less than 3 s, primarily less than 2 s and is in particular less than 1.5 s.

One improvement of the method is that the measurement period, that is to say the duration and/or frequency thereof, can be designed to be of different lengths with regard to charging mode, operating mode and idle mode.

Advantageously, in the charging mode, which is a particularly critical process because of the high charging voltage imposed from outside, a frequent measurement period should be chosen. This should be in the range from 0.5 ms to 2 s, advantageously in the range from 1 ms to 1.5 s, ideally in the range from 1.5 ms to 1 s. In the present case, the “charging mode” means the charging of the battery by a stationary charging station, not dynamic charging processes in which a vehicle charges the battery for a short time in generator mode by for example braking processes.

The measurement period in the operating mode of the battery is usually stipulated by safety routines and specifications by the manufacturers. The measurement period is in the range from 0.5ms to 1 s, advantageously in the range from 0.5 ms to 500 ms, ideally in the range from 0.5 ms to 100 ms. “Operating mode” here means that the battery is in use for operating a motor, vehicle, etc., that is to say in particular is not in the charging mode at a stationary column or in the switched-off state.

In the idle mode of the battery, one embodiment makes provision for the measurement period to be lengthened in order to save power and thus lengthen the usability of the battery. The measurement period in the idle mode should be in the range above 10 ms, advantageously in the range above 2 s, ideally in the range above 5 s. “Idle mode” here means that the battery is neither at the same time being charged at a stationary charging station nor in the operating mode.

This embodiment can be further improved by virtue of at least one further state measurement value being received and evaluated by the evaluation unit, and the measurement period and/or the frequency thereof being adapted on the basis of the at least one further state measurement value.

Such additional state measurement values can in principle be all influencing variables which have an influence on the operation and safety of a battery. State values or a combination of state values taken from the following group have proven to be particularly influential factors:
Interval of time from the operating mode of the battery or interval of time from the charging mode of the battery, because as the idle duration of a battery goes by, even after charging mode, critical thermal events are increasingly more unlikely.
Temperature of the battery, in particular during and before the respective measurement period, because a possibly overheated battery should initially be checked more frequently than a cold battery in which critical thermal events are much less likely.
Temperature curve of the battery before the respective measurement period, in particular in a defined lead-in period, because a much greater likelihood of a thermal event can be inferred from the history of a battery that possibly frequently becomes very hot than in a completely inconspicuous usage history.
Temperature in the outside area, in particular also expected temperature influence due to local conditions, because completely different thermal effects on the battery are to be expected in an idle mode in winter in northern latitudes in the evening compared to after the start of the idle mode of the battery at midday in desert regions.

The invention also encompasses a battery, in particular in the form of a high-voltage battery (HV battery), which comprises at least the following battery elements:
one or more cell packs and associated (battery) cells, a main control unit, a main processor and a plurality of electronic elements, wherein at least one pack measurement unit for the determining of the (cell) pack voltage is provided and at least one cell measurement unit for the determining of at least one cell/cell voltage, and a microprocessor which processes the measurement data by means of an analysis program, wherein by means of the microprocessor and the analysis program a method according to one of the preceding variants is able to be carried out. In this case, the microprocessor may be identical to the main processor or communicate with the main (micro) processor.

In the present case, no distinction is made between (analog) measurement values and/or and data generated directly or indirectly therefrom which are able to be used by software. Measurement values and (measurement) data should therefore be understood to be largely synonymous unless something to the contrary is expressly mentioned. Possibly required analog-to-digital converters (ADCs) and other hardware and software elements for processing and forwarding in a known way are thus to be provided by a person skilled in the art.

In one embodiment of the battery, this battery comprises a temperature sensor and/or is connected to such in a data-carrying manner, which temperature sensor is in particular arranged at or on at least one cell pack. The temperature sensor is in particular connected to the microprocessor and/or the main control unit in a data-carrying manner. Advantageously, the temperature sensor is arranged in the interior of the battery, in a battery housing. However, it can also be an external sensor.

In a further embodiment of the battery, this battery comprises at least one pressure sensor, in particular a pressure sensor on or at least one cell pack, wherein the pressure sensor is connected directly or indirectly to the microprocessor and/or the main control unit in a data-carrying manner.

In this case, “connected” or “in connection” is not to be understood in a restrictive sense and means both one or more connections for the voltage supply and current supply and also for the data-carrying communication. The communication can in particular be in the form of one of the customary bus technologies or serial interfaces, by way of separate individual cables or modulated on one or more current-carrying individual cables.

The big advantage of this solution is that a thermal event is identified immediately in a specific cell pack or a group of cell packs, in particular without relying on other sensors or detection apparatuses.

### BRIEF DESCRIPTION OF THE DRAWINGS

Further details and advantages of the invention will now be explained in more detail on the basis of an exemplary embodiment illustrated in the drawings.

In the drawings:

FIG. 1 shows an overview of a high-voltage battery and

FIG. 2 shows a graph with voltage curves at the start of a thermal event (thermal runway) and

### DETAILED DESCRIPTION

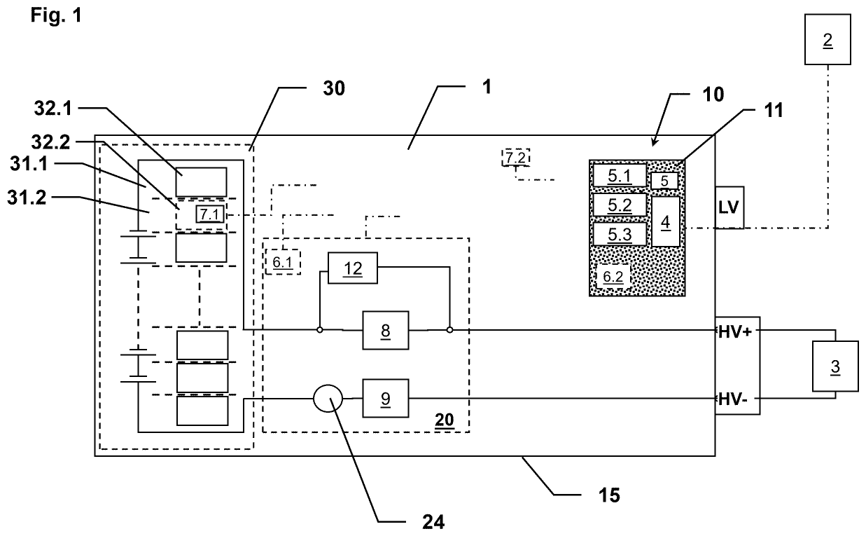

FIG. 1 shows a schematic design of a HV battery 1 which, as essential components, has a battery housing 15 inside which a main control unit 10, a switch box 20 and a cell compartment 30. The cell compartment 30 is divided into a plurality of cell packs 31.1 . . . 31.n, which has been indicated by way of a dashed, transverse line. Each cell pack 31.1 . . . 31.n has an associated cell measurement board 32.1 . . . 32.n. The main control unit 10 and the main board 11 thereof are connected to a central control and supply unit 2 in a data-and current-carrying manner via the LV line. The battery 1 is connected to one or more loads 3 via HV lines, as is indicated very schematically.

The HV+ line is routed into the switch box 20 and to the contactor 8 there, and the HV-line is routed to the contactor 9. Furthermore, there is provision for an auxiliary current path on the HV+ line in the switch box 20 in order to operate the contactor 12, which acts as a precharging contactor. Furthermore, there is provision for a current sensor 24 in the switch box 20; other fuses, resistors or further components are not illustrated. The main board 11 is connected to the switch box 20 or individual components and parts in the switch box 20, this not having been distinguished in detail in the present case. The main board 11 comprises a plurality of microelectronic/electronic elements 5.1, 5.2, 5.3 and a main microprocessor 4. In the present case, provision is made for a separate microprocessor 5 which essentially has the object of identifying thermal events and of transmitting suitable warning signals and control signals.

FIG. 1 illustrates a plurality of attachment locations for the supplementary arrangement of at least one pressure sensor 6.1, 6.2, namely on the main board 11 of the main control unit 10 and/or in the switch box 20. Two advantageous attachment locations for optional temperature sensors 7.1, 7.2 are likewise illustrated, namely on one of the cell boards 32.2 and/or in the interior of the cell compartment 30. An additional, optional CO₂ sensor should be arranged at comparable places.

Despite the somewhat slower response of the aforementioned sensors, the inclusion thereof in the monitoring routines can be very useful in verifying a voltage drop and a possible thermal event since from a logical point of view a rapid increase in temperature is for example also always subsequently associated with a thermal event.

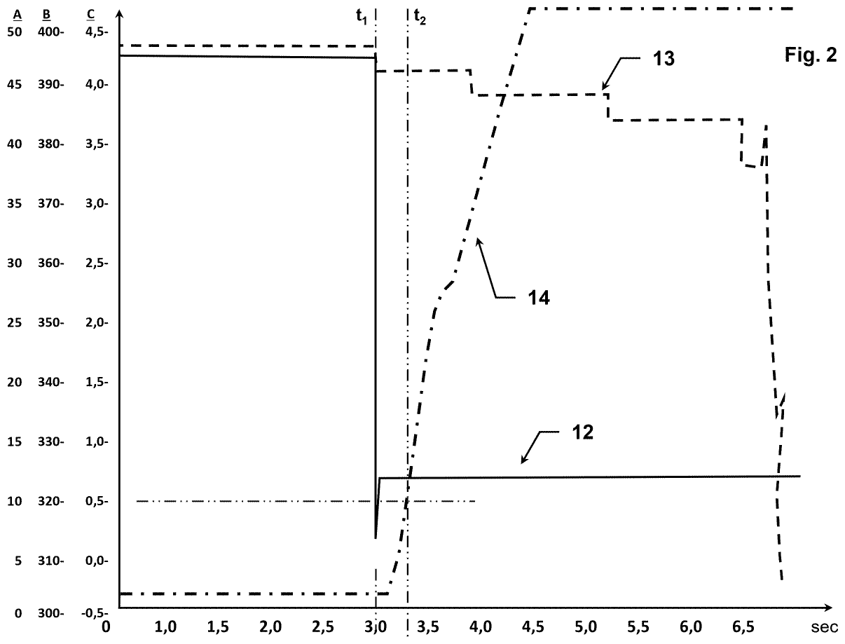

In the graphical curve of FIG. 2, an experiment carried out in the laboratory pertaining to the states of a HV battery in the case of a thermal event (thermal runaway) is illustrated on the basis of the voltage curves and of a CO₂ curve. The curve of the cell voltage 12, illustrated in the form of a solid line, relates to the C-axis values and the cell pack voltage 13 illustrated in the form of a dashed line relates to the B-axis. Furthermore, for the purpose of comparison, the curve of the CO₂ concentration in 1000 ppm is illustrated in the form of a dash-dotted line which relates to the A-axis. At the time t₁=3 s, the short circuit of the cell occurs, whereupon the cell voltage drops from an initial ˜4.1V to almost 0V (cell error value). In an event time of a few milliseconds, the cell pack voltage 13 follows and falls in one step from initially 393V to approx. 389V (pack error value). The cell voltage 12 subsequently recovers slightly and remains at a low level at approx. 0.5V. The CO₂ concentration 14 clearly follows with a delay and only at t₂=3.3 s reaches a value of approx. 10,000 ppm which a CO₂ sensor is reliably able to detect.

In this case, the mentioned value of 10,000 ppm for reliable identification depends to a large extent on the sensitivity of the sensor. In the case of an alternative reference variable, reliable identification occurs upon a multiple of customary CO2 concentrations, such as upon the occurrence of at least 1.5 to 2-times the customary CO2 concentrations during operation of a HV battery or of the vehicle.

By comparing the voltage curves, an overheating warning message can therefore be triggered approx. 0.3 s earlier.

### LIST OF REFERENCE SIGNS

1 battery

2 control and supply unit

3 load

4 main microprocessor

5 microprocessor

5.1, 5.2, 5.3 element, (micro) electronic

6.1, 6.2 pressure sensor

7 temperature sensor

8 contactor

9 contactor

10 main control unit

11 main board

12 contactor

13 voltage curve of the cell voltage [V]

14 voltage curve of the (cell) pack voltage [V]

15 curve of the concentration of CO₂[1000 ppm]

15 battery housing

20 switch box

23 secondary microprocessor

24 current sensor

30 cell compartment

31 cell pack (31.1 . . . 31.n)

32 cell measurement board (32.1 . . . 32.n)

35 level, lower

36 level, upper

1. A method for operating a battery which has a battery management system (BMS) having a main control unit comprising a main board, and comprising a plurality of cell packs, wherein a check with regard to a thermal event is carried out in regular measurement periods, wherein the following steps are performed:
determining the cell voltage of at least one battery cell,
determining the associated cell pack voltage of the at least one battery cell,
evaluating the cell voltage and the cell pack voltage by means of an analysis program on a microprocessor in the main control unit, wherein an overheating warning message is triggered if, within a defined event time,
the cell voltage decreases by a defined cell error value and
the cell pack voltage decreases by a defined pack error value.

2. The method according to claim 1, wherein the cell error value is at least 60%, compared with the cell voltage before the measurement period.

3. The method according to claim 1, wherein the pack error value corresponds at least to the cell error value, plus/minus 10%.

4. The method according to claim 1, wherein the event time during which after a cell error value a pack error value is determined is less than 3 s.

5. The method according to claim 1, wherein the measurement period in the charging mode of the battery is in the range from 0.5 ms to 2 s.

6. The method as claimed in claim 1, wherein the measurement period in the operating mode of the battery, in which a vehicle is driven by means of the battery, is in the range from 0.5 ms to 1 s.

7. The method according to claim 1, wherein the measurement period in the idle mode of the battery, in which no vehicle is driven and no charging process is carried out, is above 10 ms.

8. The method according to claim 7, wherein at least one further state measurement value is received and evaluated by the evaluation unit, and wherein at least one of: the measurement period and the frequency thereof is adapted on the basis of the at least one further state measurement value.

9. The method according to claim 8, wherein at least one or more state values is taken from the following group:
interval of time from the operating mode of the battery,
interval of time from the charging mode of the battery,
temperature of the battery, at least one of: during the respective measurement period and before the respective measurement period,
temperature curve of the battery before the respective measurement period, and
temperature in the outside area.

10. A battery, in the form of a high-voltage battery (HV battery), comprising at least the following battery elements:
a cell compartment having a plurality of cell packs and associated cells,
a main control unit having a main board, a main processor and a plurality of electronic elements, wherein
at least one pack measurement unit for the pack voltage is provided and
at least one cell measurement unit for at least one cell/cell voltage and a microprocessor which processes at least one of a digital measurement data and an analog measurement data by means of an analysis program.

11. The battery according to claim 10, wherein the battery comprises at least one temperature sensor (7), wherein the temperature sensor is connected to the main control unit in a data-carrying manner.

12. The battery according to claim 10, wherein comprising at least one pressure sensor (6), wherein the pressure sensor is connected to the main control unit in a data-carrying manner.

13. The method according to claim 1, wherein the thermal event is a thermal runaway.

14. The method according to claim 1, wherein the cell error value is at least 70% compared with the cell voltage before the measurement period.

15. The method according to claim 1, wherein the pack error value corresponds at least to the cell error value, plus/minus 5%.

16. The method according to claim 9, wherein the respective measurement period comprises a defined lead-in period, and wherein the temperature in the outside area comprises an expected temperature influence due to local conditions.

17. The battery according to claim 11, wherein the battery-comprises at least one temperature sensor at or on at least one cell pack.

18. The battery according to claim 12, wherein the at least one pressure sensor is a pressure sensor on or at least one cell pack.
